(19) United States
(12) Patent Application Publication
(10) Pub. No.: US 2010/0289513 A1
(43) Pub. Date: Nov. 18, 2010

(54) TEST SOCKET ASSEMBLY HAVING HEAT DISSIPATION MODULE

(75) Inventors: WEN-YI HSIEH, Tu-Cheng (TW); KENZO NAKAO, Yokohama (JP)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION INDUSTRY CO., LTD., Taipei Hsien (TW)

(21) Appl. No.: 12/609,020

(22) Filed: Oct. 30, 2009

(30) Foreign Application Priority Data
May 12, 2009 (TW) 98208095

(51) Int. Cl. G01R 31/02

(52) U.S. Cl. 324/755

(57) ABSTRACT

A test socket assembly (100) comprises a test socket (10) and a heat dissipation module (5) assembled on the test socket (10), the test socket (10) comprises a base (1) with a plurality of contacts (12) received therein, a cover (3) with a window (33) assembled on the base (1), the heat dissipation module (5) comprises an interlock member (53) going through the window (33) to interlock with the cover (3) to make the heat dissipation module (5) to be securely located on the test socket (10).

### BACKGROUND OF THE INVENTION

1. Field of the Invention

The present invention relates to a test socket assembly, and more particularly, to a test socket assembly having a heat dissipation module assembled thereon in use and removed therefrom readily.

2. Description of the Prior Art

A test socket is used to test an IC processor and comprises a base, a cover assembled on the base and a plurality of actuators to make the cover to move up and down relative to the base. The cover moves up and down from a closed position to an opened position. When the cover is in the opened position, the IC processor can be assembled into the test socket and disengaged from the contacts of the test socket. Then the cover is rotated to the closed position, the IC processor is in contact with the contacts to establish an electrical connection with the contacts.

Referring to FIGS. 1 to 2, a conventional test socket 9 comprises a base 91, a plurality of contacts (not shown) assembled on the base 91, a top plate 92 assembled on the base 91, a pair of actuators 95 assembled on the base 91, a pair of springs 94, a cover 93 assembled on the base 91, and a pair of press plates 96 assembled on the cover 93. The base 91 comprises a plurality of passageways 910 for receiving the contacts, a pair of holes 914 to receive the springs 94, and a receiving hole 912. The actuator 95 defines a pair of levers 950 each has a hole 951 and a slot 952. A pinshaft 954 is assembled on the receiving hole 912 of the base 91 and goes through the hole 951 of the lever 950 to assemble the lever 950 to the base 91. The top plate 92 comprises a plurality of channels 920 corresponding to the passageways 910 of the base 91 to receive the contacts. A moveable shaft 955 is assembled on a pair of second receiving holes 924 of the top plate 92 and goes through the slot 952 of lever 950 to attach the lever 950 to the top plate 92. The cover 93 is configured to a rectangular shape with four side walls 932 to define a window 930. The press plate 96 is assembled to the side wall 932.

When the test socket 9 is assembled, the top plate 92 and the cover 93 are assembled on the base 91. In use, exert a downwardly force on the cover 93 and the cover 93 presses the actuator 95 down, the moveable shaft 955 moves in the slot 952 of the lever 950 to make the top plate 92 move down. At the same time, the actuator 95 presses the springs 94. When the force is removed, the cover 93 will move up due to the re-bounce of the spring 94.

In used, this type of test socket 9 is assembled to a test equipment and the heat produced by the processor is emitted by a special heat sink assembled on the test equipment. The disadvantage is this heat sink is controlled by a machine and can not be controlled by a tester.

In view of the above, a new test socket assembly that overcomes the above-mentioned disadvantages is desired.

### SUMMARY OF THE INVENTION

Accordingly, an object of the present invention is to provide a test socket assembly having a heat dissipation module which can be assembled thereon and can be removed from the test socket assembly easily by the tester.

To fulfill the above-mentioned object, a test socket assembly comprises a test socket and a heat dissipation module assembled on the test socket, the test socket comprises a base with a plurality of contacts received therein, a cover with a window rotationally assembled on the base, the heat dissipation module comprises an interlinking member going through the window to interlock with the cover to make the heat dissipation module to be securely located on the test socket.

Other objects, advantages and novel features of the invention will become more apparent from the following detailed description when taken in conjunction with the accompanying drawings.

### BRIEF DESCRIPTION OF THE DRAWINGS

FIG. 1 is an exploded view of a conventional test socket;

FIG. 2 is an assembled view of the test socket shown in FIG. 1;

FIG. 3 is an assembled view of a test socket assembly in accordance with a preferred embodiment of the present invention;

FIG. 4 is an exploded view of the test socket assembly shown in FIG. 3, showing the heat dissipation module not assembled on the test socket and the processor being assembled to the test socket;

FIG. 5 is an exploded view of the test socket shown in FIG. 3;

FIG. 6 is another exploded view of the test socket showing the cover is detached therefrom;

FIG. 7 is an exploded view of the heat dissipation module shown in

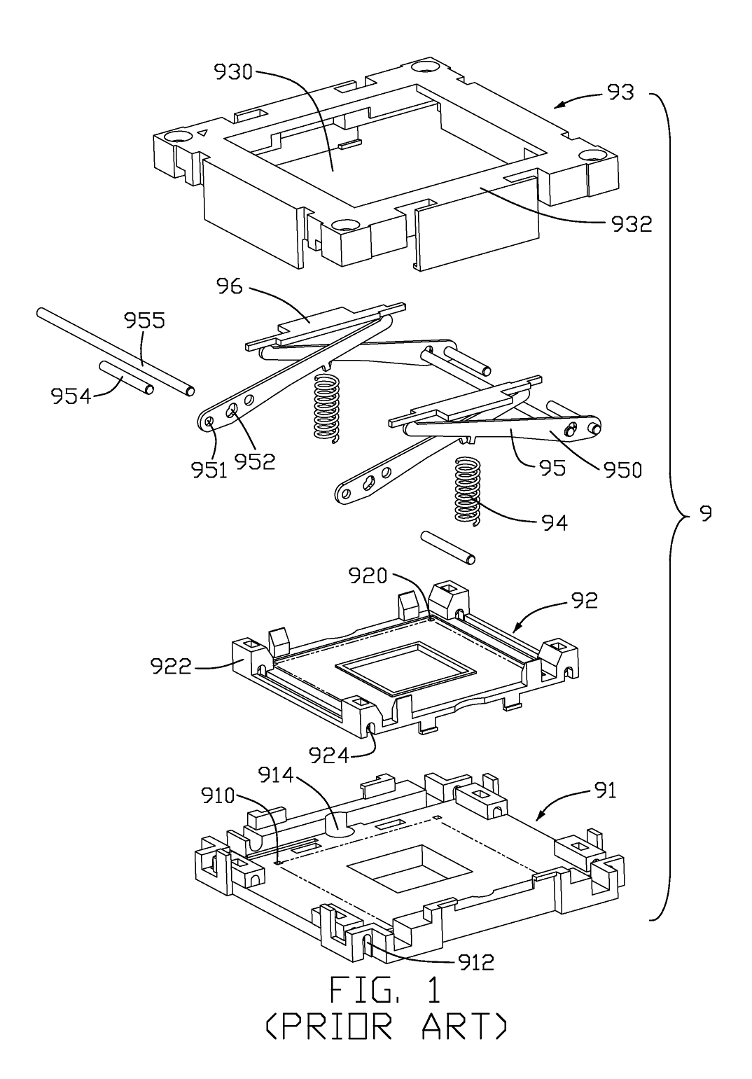

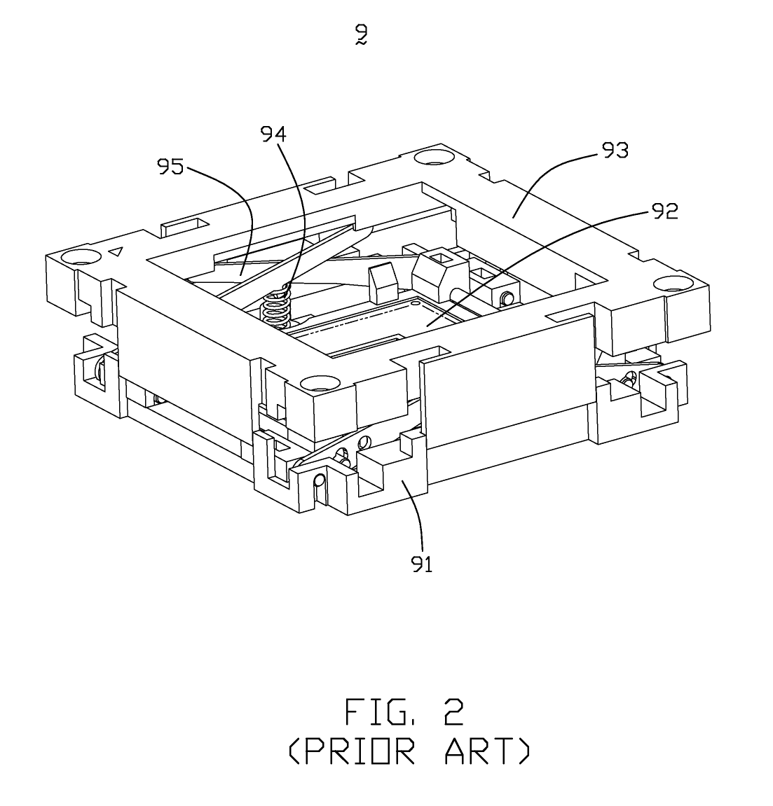

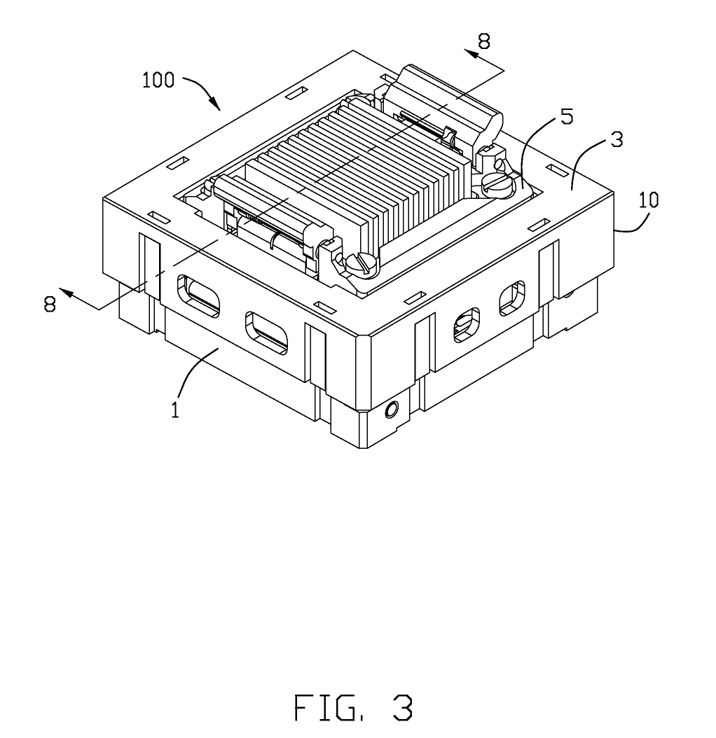

FIG. 3;

FIG. 8 is a cross-sectional view of the test socket assembly taken along line 8-8 in a first position of FIG. 3;

FIG. 9 is similarly to FIG. 8, showing the heat dissipation module in a second position; and

FIG. 10 is similar to FIG. 8, showing the heat dissipation module in a third position.

### DETAILED DESCRIPTION OF THE PREFERRED EMBODIMENT OF THE INVENTION

Reference will now be made to the drawings to describe the present invention in detail.

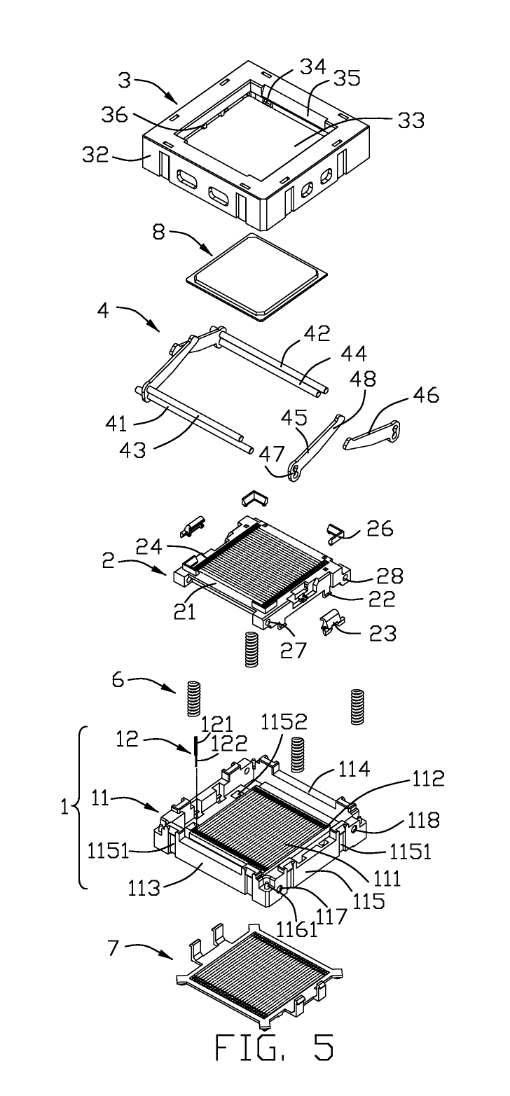

Referring to FIGS. 3-5, a test socket assembly 100 in accordance with the present invention is used to test a processor 8 and comprises a test socket 10 and a heat dissipation module 5 assembled on the test socket 10. The test socket 10 comprises a base 1, a top plate 2 and a cover 3 assembled on the base 1, an actuator 4 assembled on the base 1 and the top plate 2, and a bottom plate 7 assembled to the base 1.

The base 1 comprises an insulative housing 11 and a plurality of contacts 12 received therein. The insulative housing 11 is configured to a rectangular shape and defines a plurality of passageways 112 to receive the contacts 12 and a first receiving slot 1152 near the passageways 112. There is a post 1161 on each corner of the insulative housing 11. The insulative housing 11 has a front side 113, a rear side 114, and a left and right side 115 with a pair of slots 1151 at the two ends. The two sides 115 each defines a first hole 117 near the front side 113 and a second hole 118 near the rear side 114.

The top plate 2 is configured to a plate shape and comprises a body portion 21 to support the processor 8, a pair of hooks 22 extending downwardly from the body portion 21 and a pair of lock members 23 assembled to the two sides of the body portion 21. The body portion 21 defines a plurality of channels 24 corresponding to the passageways 112 of the insulative housing 11 to receive the two arms 121 of the contact 12, a plurality of third holes 27 and fourth holes 28 defined at corners thereof. The top plate 2 also defines four blocks 26 assembled to the body plate 21 to form a receiving space for receiving the processor 8. When the top plate 2 is assembled to the base 1, the hooks 22 go through the first receiving slot 1152 to interlock with the base 1, thereby making the top plate 2 be assembled on the base 1 securely. The hooks 22 can move in the first receiving slot 1152 horizontally to make the top plate 2 to move along the horizontal direction. The lock members 23 can be urged to move from the opened position to the closed position.

The cover 3 has four sidewalls 32 and a window 33 formed therebetween. The processor 8 can be put on the top plate 2 through the window 33. The sidewall 32 comprises a pair of interlock members 34 positioned in the slots 1151 of the base 1 and can move up and down to make the cover 3 to move up and down accordingly. There are four springs 6 assembled between the sidewalls 32 and the base 1. One end of the spring 6 is assembled on the post 1161 of the base 1 to make the spring 6 to be located on the base 1 securely. The inner side of the sidewall 32 defines a guiding surface 35 and the sidewall 32 defines a pair of press portions 36 at bottom ends thereof.

The actuator 4 is assembled on the base 1 and the top plate 2 and comprises a first shaft 41 received in the first hole 117, a second shaft 42 received in the second hole 118 of the base 1, a third shaft 43 received in the third hole 27 and a fourth shaft 44 received in the fourth hole 28 of the top plate 2. A first lever 45 is assembled to the first shaft 41 and the third shaft 43, and a second lever 46 is assembled to the second shaft 42 and the fourth shaft 44. The first lever 45 is intersected with the second lever 46 and comprises a first end 47 for assembling the shafts 41, 42, 43, 44 and a second end 48 opposite to the first end 47. When the cover 3 is pressed down, the press portions 36 of the cover 3 presses the second end 48 of the levers 45, 46 to rotate about the first shaft 41 and the second shaft 42 thereby driving the top plate 2 to move along the horizontal direction.

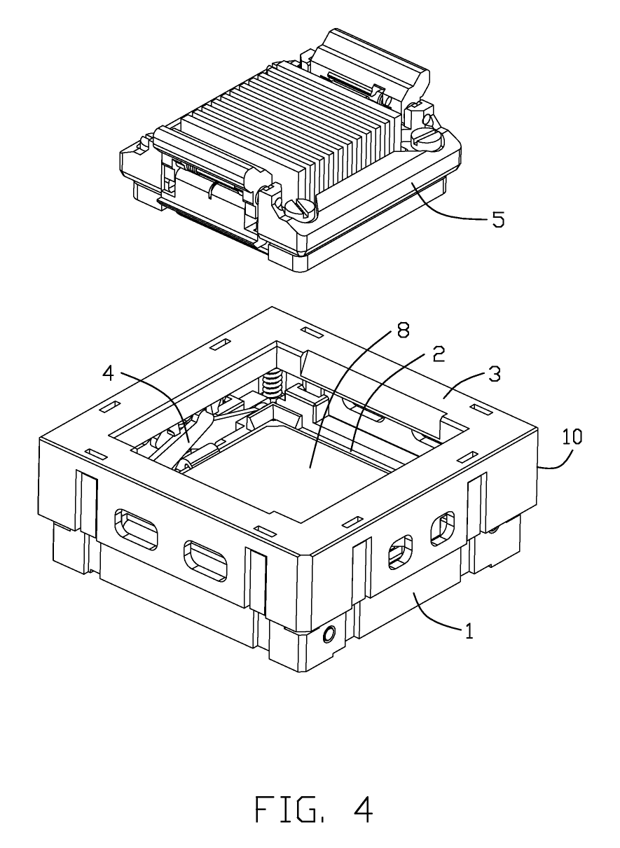

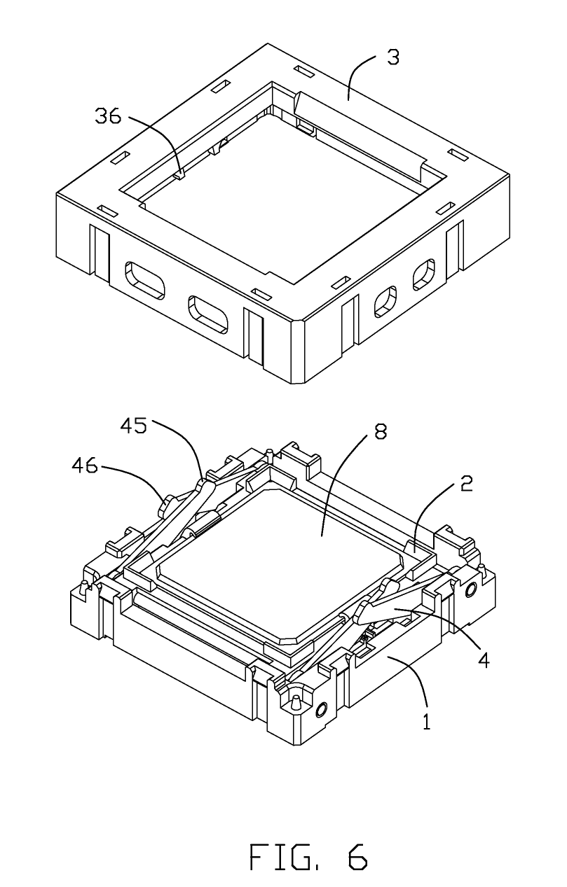

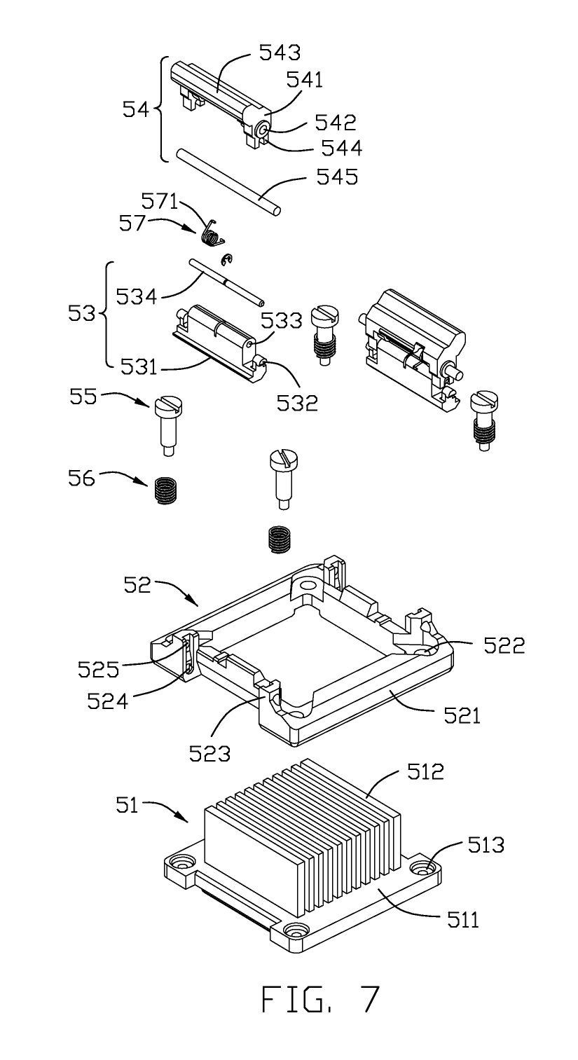

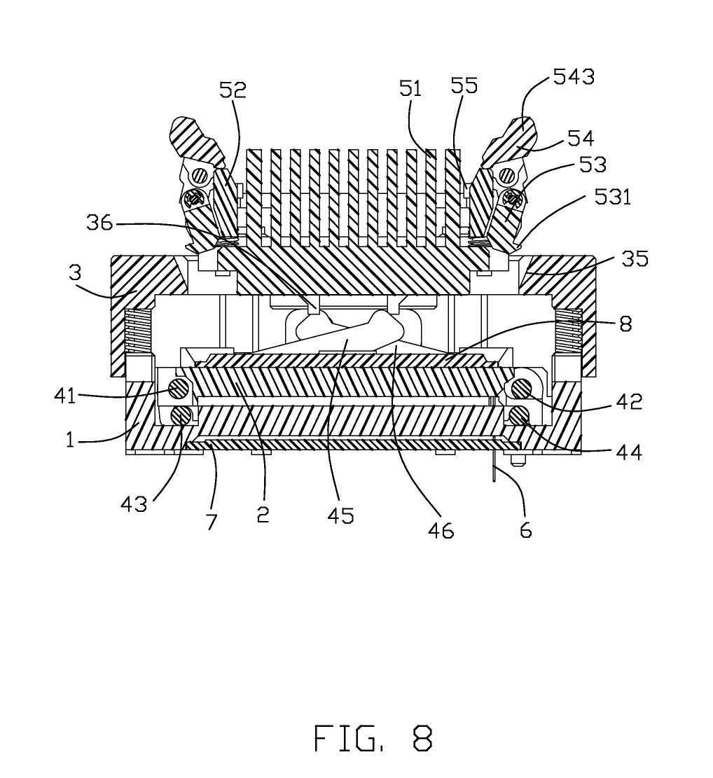

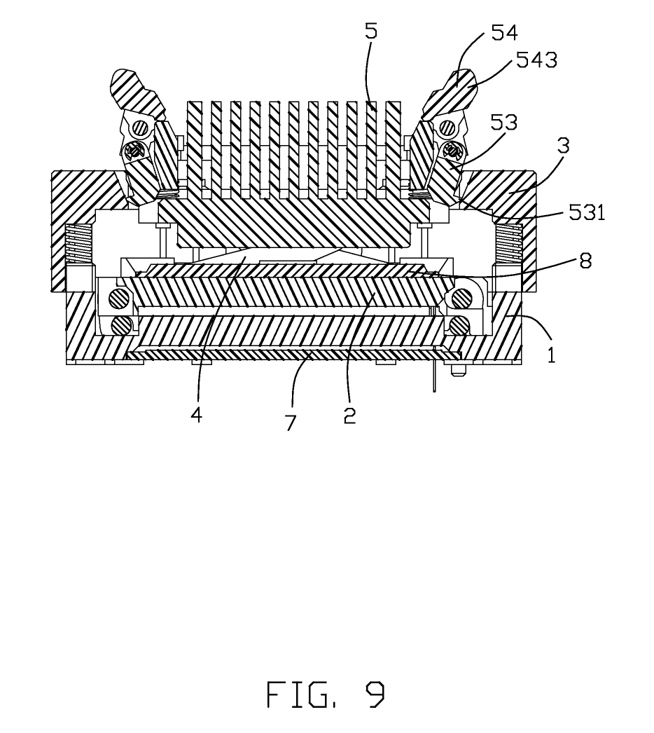

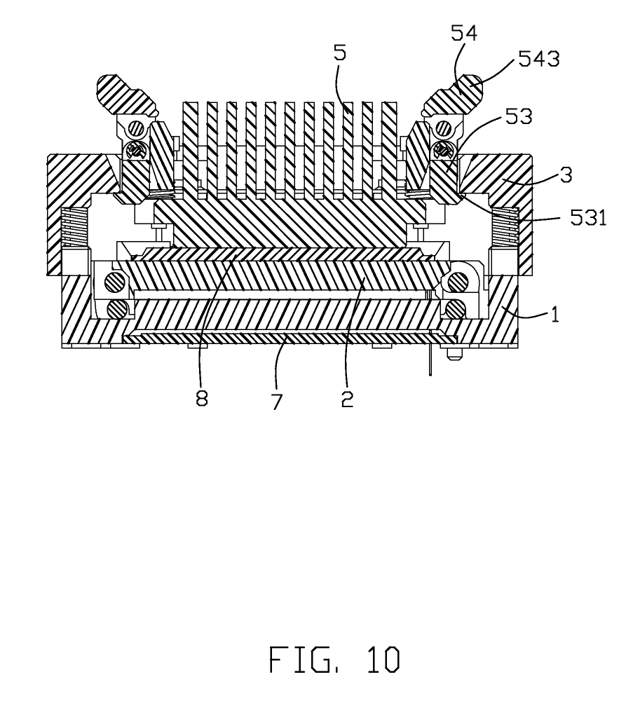

Referring to FIGS. 4 to 7, the heat dissipation module 5 is used to press the processor 8 and interlock with the cover 3. The heat dissipation module 5 comprises a heat radiator 51, a frame 52 assembled to the heat radiator 51, a pair of interlock members 53 and a pair of operation members 54 assembled to the frame 52. The heat radiator 51 comprises a planar body portion 511 and a plurality of radiation fin 512 extending upwardly from the body portion 511. The body portion 511 defines a plurality of fix holes 513 at corners thereof.

The frame 52 is assembled to the heat radiator 51 and has a plurality of edge portions 521. A plurality of through holes 522 are provided on the corners of the frame corresponding to the fix holes 513 of the heat radiator 51. A pair of edge portions 521 each comprises a pair of poles 523 extending upwardly and spaced with each other. The interlock member 53 is assembled between the pair of poles 523 and the operation member 54 is assembled between the other pair of poles 523. There are four fix members 55 going through the through holes 522 of the frame 52 and the fix holes 513 of the heat radiator 51 to position the frame 52 on the heat radiator 51 securely. There is a spring 56 assembled to the fix member 55 to make the frame 52 to move up and down relative to the heat radiator 51.

The interlock member 53 comprises a pair of fastening members 532, a first hole 533 impenetrable therethrough and a hook 531. A first pin 534 goes through the first hole 533 and two ends of the first pin 534 is located beside the first hole 533. The fastening members 532 engage with the bottom holes 524 of the frame 52 to position the interlock member 53 on the frame 52 securely and make the interlock member 53 rotate about the fastening members 532. The operation member 54 comprises a base portion 541 with a second hole 542 and an operation portion 543 extending upwardly from the base portion 541. There is a groove 544 at free end of the base portion 541 to receive the first pin 534, whereby making the interlock member 53 to rotate with the operation member 54. There is a second pin 545 goes through the second hole 542 and the second pin 534 is received in the two upper holes 525 to secure the operation member 54 on the frame 52. The operation member 54 can rotate about the second pin 545. There is a holding member 57 assembled on the operation member 54, which comprises a pair of spring arms 571 arranged with a certain angle therebetween. One of the spring arms 571 is engaged with the edge portion 521 of the frame 52, and the other spring arm 571 is engaged with the base portion 541 of the operation member 54. When there is no force exerted on the operation portion 543, the interlock member 53 can be positioned on the vertical direction securely.

When the test socket assembly 100 is assembled, the top plate 2 is mounted to the base 1, the actuator 4 is attached to the top plate 2 and the base 1, the cover 3 is assembled to the base 1, the springs 6 are located between the cover 3 and the base 1, the bottom plate 7 is secured to the base 1 from the bottom end, and the heat dissipation module 5 is assembled to the cover 3. In use, a downward force is exerted on the cover 3, the press portions 36 of the cover 3 press the first lever 45 and the second lever 46 of the actuator 4, so that the top plate 2 moves in the horizontal direction and the lock members 23 are in the opened position, then the processor 8 can be put on the top plate 2. When the force is removed, the cover 93 will move up so that the top plate 2 moves to close the lock members 23, then the processor 8 is pressed by the lock members 23 and make an electrically connection with the contacts 12.

Referring to FIGS. 8 to 10, which shows the operation process of the heat dissipation module 5. Firstly, a force is exerted on the operation portions 543 of the operation members 54 to rotate outwardly, thereby urging the hooks 531 to rotate inwardly. Secondly, the heat dissipation module 5 extends through the window 33 of the cover 3 to press on the processor 8. The guiding surface 35 leads the hooks 531 of the interlock member 53 goes through the window 33 of the cover 3. Thirdly, when the force exerted on the operation portions 543 is released, the operation members 54 is released to the original position to urge the interlock member 53 rotated outwardly, then the hooks 531 of the interlock member 53 interlock with the sidewall 32 of the cover 3 to make the heat dissipation module 5 to be securely positioned on the test socket 10.

When the test is accomplished, a force is exerted on the two operation portions 543 of the operation members 54 to make the two operation members 54 to be rotated outwardly, which urges the hooks 531 to rotate inwardly, the hooks 531 are disengaged with the sidewall 32 of the cover 3, then the dissipation module 5 can be removed from the test socket 10.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A test socket assembly comprising:
a test socket comprising a base with a plurality of contacts received therein, and a cover having a window assembled on the base; and
a heat dissipation module assembled on the test socket and comprising an interlock member going through the window to interlock with the cover to secure the heat dissipation module on the test socket.

2. The test socket assembly as claimed in claim 1, wherein the interlock member comprises a hook, and the heat dissipation module comprises an operation member to urge the hook of the interlock member to interlock or disengage with the cover.

3. The test socket assembly as claimed in claim 2, wherein a first pin goes through the interlock member and the operation member to secure the interlock member to the operation member, and make the interlock member rotate relative to the operation member.

4. The test socket assembly as claimed in claim 3, wherein the heat dissipation module comprises a heat radiator and a frame assembled to the heat radiator.

5. The test socket assembly as claimed in claim 4, wherein the interlock member comprises a pair of fastening members engages with the frame to make the interlock member to be securely located on the frame and rotate about the fastening members.

6. The test socket assembly as claimed in claim 4, wherein the operation members are assembled to the frame through a second pin, and the operation members rotate about the second pin.

7. The test socket assembly as claimed in claim 1, wherein the test socket comprises a top plate assembled on the base and an actuator assembled on the base and the top plate.

8. The test socket assembly as claimed in claim 7, wherein the actuator comprises a first shaft and a second shaft engaged with the base, a third shaft and a fourth shaft engaged with the top plate, a first lever with a first end assembled to the first shaft and the third shaft, and a second lever with a first end assembled to the second shaft and the fourth shaft.

9. The test socket assembly as claimed in claim 8, wherein the first lever is crossed with the second lever, and the cover presses the first lever and the second lever to rotate.

10. A test socket assembly comprising:
a test socket comprising a base with a plurality of contacts received therein, and a cover with a window assembled on the base, the cover moving up and down relative to the base; and
a heat dissipation module assembled on the cover and comprising an interlock member going through the window to interlock with the cover to make the heat dissipation module to be securely located on the cover.

11. The test socket assembly as claimed in claim 10, wherein the interlock member comprises a hook, and the heat dissipation module comprises an operation member to urge the hook to interlock or disengage with the cover.

12. The test socket assembly as claimed in claim 11, wherein a first pin goes through the interlock member and the operation member to secure the interlock member to the operation member, and make the interlock member rotate relative to the operation member.

13. The test socket assembly as claimed in claim 12, wherein the heat dissipation module comprises a heat radiator and a frame assembled to the heat radiator.

14. The test socket assembly as claimed in claim 13, wherein the interlock member comprises a pair of fastening members engages with the frame to make the interlock member to be securely located on the frame and rotate about the fastening members.

15. The test socket assembly as claimed in claim 13, wherein the operation members are assembled to the frame through a second pin, and the operation members rotate about the second pin.

16. The test socket assembly as claimed in claim 10, wherein the test socket comprises a top plate assembled on the base and an actuator assembled on the base and the top plate.

17. The test socket assembly as claimed in claim 16, wherein the actuator comprises a first shaft and a second shaft engaged with the base, a third shaft and a fourth shaft engaged with the top plate, a first lever with a first end assembled to the first shaft and the third shaft, and a second lever with a first end assembled to the second shaft and the fourth shaft.

18. A test socket assembly comprising:
a test socket and a heat dissipation cooperating with each other,
said socket including:
an insulative base with a plurality of contacts therein;
a cover up and down located upon and moveable relative to the base via a set of first springs constantly urging upwardly said cover away from the base;
a first receiving cavity defined in the base for receiving an electronic package;
said heat dissipation module including a frame latched to the socket;
a heat radiator assembled to the associated with the frame in a floating manner via a set of second spring constantly urging downwardly said heat radiator toward the base so as to assure said heat radiator is received in a second receiving cavity defined in the cover when the frame is latched to the socket; wherein
attachment/detachment of the heat dissipation module with regard to the socket is essentially in a vertical direction.

19. The test socket assembly as claimed in claim 18, wherein said frame is latched to the cover of the socket.

20. The test socket assembly as claimed in claim 19, wherein there are two opposite latches respectively located two opposite ends of the frame to latch the frame to the cover.
